(19) United States
(12) Patent Application Publication
(10) Pub. No.: US 2018/0151395 A1
(43) Pub. Date: May 31, 2018

(54) CLEANING COMPOSITION, CLEANING APPARATUS, AND METHOD FOR MANUFACTURING SEMICONDUCTOR DEVICE

(71) Applicant: SAMSUNG ELECTRONICS CO., LTD., Suwon-si (KR)

(72) Inventors: MIHYUN PARK, SEONGNAM-SI (KR); JUNG-MIN OH, INCHEON (KR); INGI KIM, HWASEONG-SI (KR); SEOHYUN KIM, HWASEONG-SI (KR); TAE-HONG KIM, SEOUL (KR); HYOSAN LEE, HWASEONG-SI (KR)

(21) Appl. No.: 15/819,550

(22) Filed: Nov. 21, 2017

(30) Foreign Application Priority Data
Nov. 25, 2016 (KR) 10-2016-0158658

(51) Int. Cl. H01L 21/67; H01L 21/02; H01L 29/66; H01L 21/28; H01L 21/3105; C11D 1/12; C11D 3/43

(52) U.S. Cl. CPC H01L 21/67051; H01L 21/02065; H01L 21/02074; H01L 29/66545; C11D 3/43; H01L 21/28123; H01L 21/31053; C11D 1/12; H01L 29/66803

(57) ABSTRACT

A cleaning composition includes a surfactant, deionized (DI) water, and an organic solvent. The surfactant has a concentration of from about 0.03 M to about 0.003 M. A cleaning apparatus includes a chuck that receives a substrate, a nozzle for providing the cleaning composition onto the substrate. The cleaning apparatus further includes a chemical solution supply unit supplying the cleaning composition to the nozzle. The chemical solution supply unit mixes the cleaning composition to generate cleaning particles. The cleaning composition includes a surfactant, deionized (DI) water, and an organic solvent. The surfactant has a concentration of from about 0.03 M to about 0.003 M. A method for manufacturing a semiconductor device includes processing a substrate, forming an interlayer insulating layer, polishing an interlayer insulating layer, and providing a cleaning composition onto the interlayer insulating layer to remove first particles.

### CROSS-REFERENCE TO RELATED APPLICATION

This application claims priority under 35 U.S.C. § 119 to Korean Patent Application No. 10-2016-0158658, filed on Nov. 25, 2016, in the Korean Intellectual Property Office (KIPO), the disclosure of which is incorporated by reference herein in its entirety.

### TECHNICAL FIELD

Exemplary embodiments of the inventive concepts relate to a method for manufacturing a semiconductor device and, more particularly, to a cleaning composition capable of removing process particles, a cleaning apparatus using the same, and a method for manufacturing a semiconductor device by using the same.

### DISCUSSION OF RELATED ART

With the development of the semiconductor devices, highly integrated semiconductor devices with finer patterns and a multi-layered circuit structure are in demand. In addition, developing a cleaning process for removing process particles may be necessary for preventing fine patterns from being contaminated. For example, a standard cleaning 1 (SC-1) solution may be used as a cleaning solution in the cleaning process. The SC-1 solution may include ammonia water and hydrogen peroxide. The SC-1 solution may provide repulsive force after etching a surface, thereby removing the process particles from the surface. However, the SC-1 solution may cause damages of a layer by the etching of the surface.

### SUMMARY

According to an exemplary embodiment of the present inventive concept, a cleaning composition includes a surfactant, deionized (DI) water, and an organic solvent. The surfactant has a concentration of from about 0.03 M to about 0.003 M.

According to an exemplary embodiment of the present inventive concept, a cleaning apparatus includes a chuck which receives a substrate, a nozzle that provides a chemical solution onto the substrate. The cleaning apparatus further includes a chemical solution supply unit for supplying the chemical solution to the nozzle. The chemical solution supply unit mixes the chemical solution to generate cleaning particles. The chemical solution includes a surfactant, deionized (DI) water, and an organic solvent. The surfactant has a concentration of from about 0.03 M to about 0.003 M.

According to an exemplary embodiment of the present inventive concept, a method for manufacturing a semiconductor device includes processing a substrate, forming an interlayer insulating layer on the substrate, polishing the interlayer insulating layer. The method further includes providing a cleaning composition onto the interlayer insulating layer to remove first process particles. The cleaning composition comprises a surfactant, deionized (DI) water, and an organic solvent. The surfactant has a concentration of from about 0.03 M to about 0.003 M.

According to an exemplary embodiment of the present inventive concept, a cleaning composition includes a surfactant, deionized (DI) water, and an organic solvent. The surfactant has a concentration of about 0.32 M.

### BRIEF DESCRIPTION OF THE DRAWINGS

The above and other features of the present inventive concept will become more apparent by describing in detail exemplary embodiments thereof with reference to the accompanying drawings, in which:

FIG. 1 is a plan view illustrating equipment for manufacturing a semiconductor device according to an exemplary embodiment of the present inventive concept.

FIG. 2 is a view illustrating an embodiment of a cleaning apparatus of FIG. 1 according to an exemplary embodiment of the present inventive concept.

FIG. 3 is a graph illustrating a cleaning efficiency of a chemical solution and a cleaning efficiency of a general standard cleaning 1 (SC-1) solution with respect to a size of process particles of FIG. 2 according to an exemplary embodiment of the present inventive concept.

FIG. 4 is a view illustrating an embodiment of a chemical solution supply unit of FIG. 2 according to an exemplary embodiment of the present inventive concept.

FIG. 5 is a perspective view illustrating an embodiment of cleaning particles of FIG. 4 according to an exemplary embodiment of the present inventive concept.

FIG. 6 is a graph illustrating a process particle removal efficiency of a chemical solution having the cleaning particles of FIG. 5 and a process particle removal efficiency of a chemical solution not having cleaning particles according to an exemplary embodiment of the present inventive concept.

FIG. 7 is a graph illustrating a removal efficiency of process particles according to a lateral length of the cleaning particles of FIG. 5 according to an exemplary embodiment of the present inventive concept.

FIG. 8 is a view illustrating an embodiment of circulation filters of FIG. 4 according to an exemplary embodiment of the present inventive concept.

FIG. 9 is a graph illustrating a process particle removal efficiency with respect to a mixing speed of the chemical solution of FIG. 4 according to an exemplary embodiment of the present inventive concept.

FIGS. 10 and 11 are a perspective view and a plan view illustrating a semiconductor device according to exemplary embodiments of the present inventive concepts, respectively.

FIG. 12 is a flow chart illustrating a method for manufacturing the semiconductor device of FIGS. 10 and 11 according to an exemplary embodiment of the present inventive concept.

FIG. 13 is a flow chart illustrating an embodiment of step of processing a substrate of FIG. 10 according to an exemplary embodiment of the present inventive concept.

FIGS. 14 to 28 are cross-sectional views taken along a line I-I′ of FIG. 11 to illustrate a method for manufacturing a semiconductor device according to exemplary embodiments of the inventive concept.

FIG. 29 is a view illustrating dielectric particles and cleaning particles of FIG. 24 according to an exemplary embodiment of the present inventive concept.

FIG. 30 is a view illustrating metal particles and cleaning particles of FIG. 28 according to an exemplary embodiment of the present inventive concept.

### DETAILED DESCRIPTION

Exemplary embodiments of the present inventive concept will be described more fully with reference to the accompanying drawings. The present disclosure may, however, be embodied in many different forms and should not be construed as limited to the embodiments set forth herein. It will be understood that when an element is referred to as being “connected” to another element, it can be directly connected to the other element or intervening element may be present.

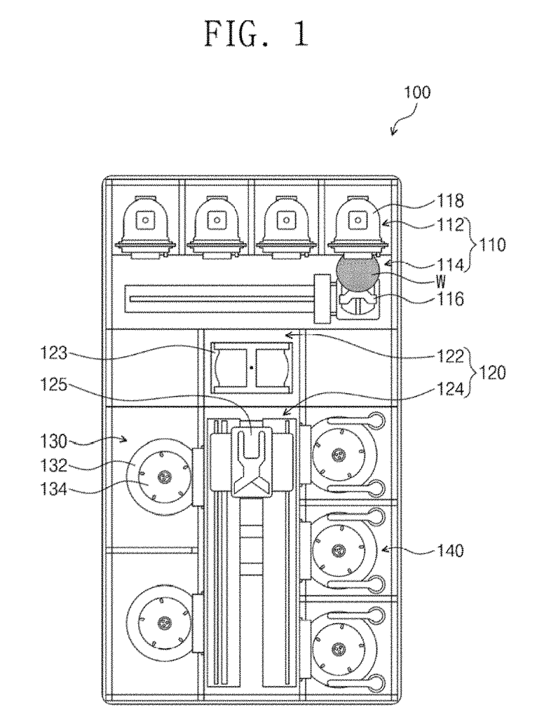

FIG. 1 illustrates equipment 100 for manufacturing a semiconductor device, according to an exemplary embodiment of the present inventive concepts.

An equipment 100 for manufacturing a semiconductor device may include a chemical mechanical polishing (CMP) equipment. Alternatively, the equipment 100 for manufacturing a semiconductor device may include a cleaning equipment or an etching equipment. In other embodiments, the equipment 100 for manufacturing a semiconductor device may include an index apparatus 110, a transfer apparatus 120, a polishing apparatus 130, and/or a cleaning apparatus 140.

The index apparatus 110 may temporarily store a cassette 118. The cassette 118 may receive a substrate W. In other embodiments, the index apparatus 110 may include a load port 112, a transfer frame 114, and/or an index arm 116. The load port 112 may receive the cassette 118 in the load port 112. The cassette 118 may include a front opening unified pod (FOUP). The transfer frame 114 may include the index arm 116. The index arm 116 may unload the substrate W received in the cassette 118, and may transfer the unloaded substrate W to the transfer apparatus 120. In addition, the index arm 116 may load the substrate W into the cassette 118.

The transfer apparatus 120 may transfer the substrate W into the polishing apparatus 130 and the cleaning apparatus 140. In other embodiments, the transfer apparatus 120 may include a buffer chamber 122 and a transfer chamber 124. The buffer chamber 122 may be disposed between the transfer frame 114 and the transfer chamber 124. The buffer chamber 122 may include a buffer arm 123, and the buffer arm 123 may receive the substrate W. The index arm 116 may provide the substrate W onto the buffer arm 123. In addition, the index arm 116 may transfer the substrate W disposed on the buffer arm 123 into the cassette 118. The transfer chamber 124 may be disposed between the polishing apparatus 130 and the cleaning apparatus 140. A transfer arm 125 in the transfer chamber 124 may provide the substrate W disposed on the buffer arm 123 into the polishing apparatus 130. In addition, the transfer arm 125 may transfer the substrate W between the polishing apparatus 130 and the cleaning apparatus 140. Furthermore, the transfer arm 125 may transfer the substrate W between the cleaning apparatus 140 and the buffer arm 123.

The polishing apparatus 130 may polish the substrate W. For example, the polishing apparatus 130 may be a chemical mechanical polishing (CMP) apparatus. In other embodiments, the polishing apparatus 130 may include a polishing pad 132 and a polishing head 134. The substrate W may be provided between the polishing pad 132 and the polishing head 134 for polishing. In addition, an abrasive and/or slurry may be provided onto the substrate W. The polishing head 134 may fix the substrate W to the polishing head 134. The polishing pad 132 may polish the substrate W.

The cleaning apparatus 140 may remove process particles on the substrate W. The cleaning apparatus 140 may clean the substrate W by a wet cleaning method. Alternatively, the cleaning apparatus 140 may clean the substrate W by a dry cleaning method.

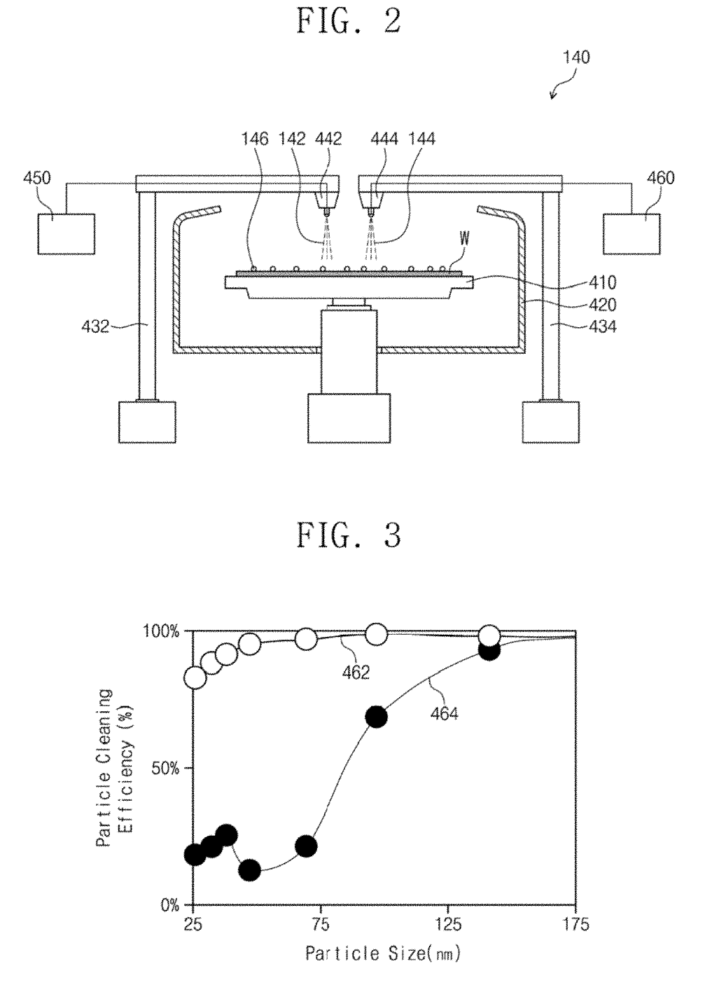

FIG. 2 illustrates an embodiment of the cleaning apparatus 140 of FIG. 1 according to an exemplary embodiment of the present inventive concept. Referring to FIG. 2, the cleaning apparatus 140 may include a chuck 410, a bowl 420, first and second arms 432 and 434, first and second nozzles 442 and 444, a first deionized (DI) water supply unit 450 fluidly connected to the first nozzle 442, and a chemical solution supply unit 460 fluidly connected to the second nozzle 444.

The chuck 410 may receive the substrate W. The substrate W may be fixedly coupled to the chuck 410 by operation of vacuum pump (not shown). The chuck 410 may rotate the substrate W at a predetermined rotational speed. For example, the chuck 410 may rotate the substrate W at a rotational speed of from about 10 rpm to about 6000 rpm. First DI water 142 or a chemical solution 144 may be provided to the surface of the substrate W, and may move toward the periphery of the substrate W by centrifugal force. That way, cleaning of the substrate W may be performed.

The bowl 420 may surround the substrate W to receive the substrate W in the bowl 420. Once provided on the substrate W, the first DI water 142 and/or the chemical solution 144 may move in a direction from the substrate W to the bowl 420 by centrifugal force. The bowl 420 may prevent an outflow of the first DI water 142 and/or the chemical solution 144 provided on the substrate W. The bowl 420 may exhaust the first DI water 142 and/or the chemical solution 144 to a space underneath the chuck 410 in the bowl 420. The bowl 420 may prevent the substrate W from being contaminated.

The first and second arms 432 and 434 may fix the first and second nozzles 442 and 444 at a predetermined position, respectively. The first nozzle 442 may be connected to an upper portion of the first arm 432. The second nozzle 444 may be connected to an upper portion of the second arm 434. The first and second arms 432 and 434 may move the first and second nozzles 442 and 444 positioned above the substrate W, respectively. For example, the first and second arms 432 and 434 may move around above the substantially center portion of the substrate W.

The first and second nozzles 442 and 444 may provide the first DI water 142 and the chemical solution 144 onto the substrate W, respectively. For example, the first and second nozzles 442 and 444 may provide the first DI water 142 and the chemical solution 144 at a pressure of about 1 atmosphere to about 10 atmospheres. The first DI water 142 and the chemical solution 144 may be provided in the form of droplets or spray. The first DI water 142 and the chemical solution 144 may be provided onto the substantially center portion of the substrate W. The first DI water 142 and the chemical solution 144 may be provided to clean the substrate W from the substantially center portion of the substrate W to the periphery of the substrate W. The first DI water 142 and the chemical solution 144 may remove process particles 146 disposed on the substrate W.

The first DI water supply unit 450 may provide the first DI water to the first nozzle 442. The first DI water 142 may be a cleaning solution. For example, the first DI water supply unit 450 may include a water purifier.

The chemical solution supply unit 460 may provide the chemical solution 144 to the second nozzle 444. The chemical solution 144 may be the cleaning solution and/or a cleaning composition. The cleaning composition may include a surfactant, second DI water, and/or an organic solvent, and the surfactant may have a concentration of from about 0.03 M to about 0.003 M in the diluted solution. For example, a pH of the chemical solution 144 may be set to be about 9 or higher. In one embodiment, when the pH of the chemical solution 144 is substantially high, repulsive force between the process particles 146 in the chemical solution 144 may be increased. In another embodiment where the pH of the chemical solution 144 is substantially high, repulsive force between the substrate W and the process particles 146 disposed in the chemical solution 144 may be increased.

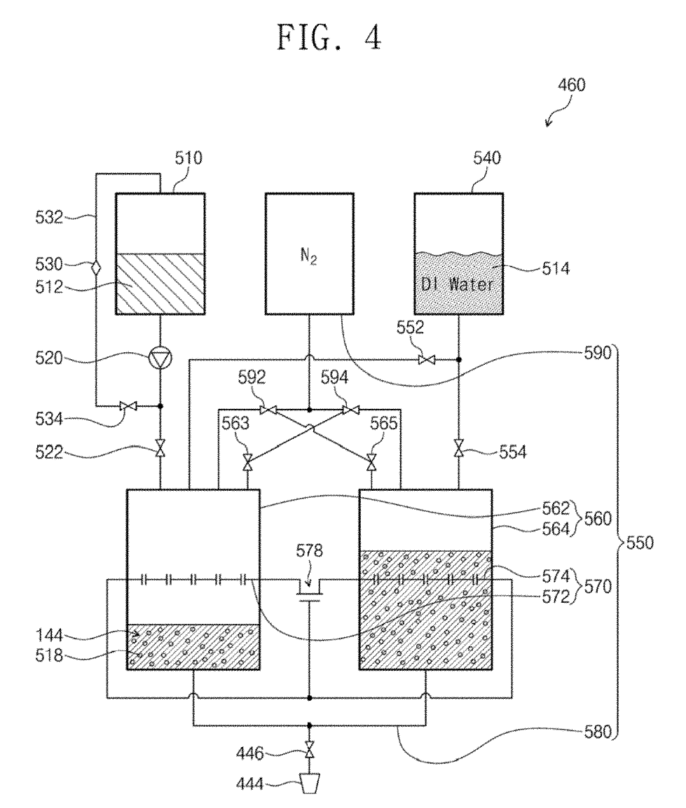

In some embodiments, the chemical solution 144 may include a surfactant, second DI water (514 of FIG. 4), and/or an organic solvent. The organic solvent may include isopropyl alcohol (IPA), ethyl alcohol (EtOH), methanol (MeOH), a solvent of dimethyl sulfoxide (DMSO), a solvent of dimethylformamide (DMF), a solvent of ethylene glycol (EG), a solvent of propylene glycol (PG), a solvent of terahydrofuran (THF), a solvent of N-methyl-2-pyrrolidone (NMP), or a solvent of N-ethylpyrrolidone (NEP). Alternatively, the organic solvent may include dimethyl sulfoxide (DMSO), dimethylformamide (DMF), tetrahydrofuran (THF), ethylene glycol (EG), propylene glycol (PG), and/or N-methyl-2-pyrrolidone (NMP). The surfactant may include a negative-ion surfactant. The surfactant may be a sulfate-based compound having a structure represented by the following chemical formula 1.

(R¹—O)ₙ—(R²—O)_{b}—SO₃NH₄ [Chemical formula 1]

Here, each of “a” and “b” is an integral number of 0 to 18, “a” and “b” are not being zero (0) at the same time, “R¹” and “R²” are a substituted or unsubstituted alkyl or alkylene group having a carbon number of 1 to 18 or a substituted or unsubstituted arylene group having a carbon number of 6 to 14, and (R¹—O) or (R²—O) is randomly repeated or is repeated in a block form when “a” or “b” is 3 or greater. For example, when “a” is 1, the carbon number of “R¹” is 16 and “b” is 0, the surfactant may include ammonium hexadecyl sulfate (CH₃(CH₂)₁₄CH₂—SO₃NH₄). The surfactant may increase cleaning efficiency of the process particles 146.

FIG. 3 illustrates a cleaning efficiency 462 of the chemical solution 144 and a cleaning efficiency 464 of a general SC-1 solution with respect to a size of the process particles 146 of FIG. 2 according to an exemplary embodiment of the present inventive concept. FIG. 3 illustrates that, for the process particles 146 having sizes of about 100 nm or less, the cleaning efficiency 462 of the chemical solution 144 may be substantially higher than the cleaning efficiency 464 of the general SC-1 solution. For example, the cleaning efficiency 462 of the chemical solution 144 may be at least about 87% with respect to the process particles 146 having sizes of about 45 nm or less. On the other hand, the cleaning efficiency 464 of the general SC-1 solution may be about 21% with respect to the process particles 146 having sizes of about 45 nm or less. The general SC-1 solution may be provided to the process particles 146 at a high pressure of about 2 atmospheres or greater. If a portion of an upper surface of the substrate W is damaged by the high pressured general SC-1 solution, the process particles 146 may be generated again. Thus, fine (small sized) process particles 146 having the sizes of about 45 nm or less may not be easily removed from the substrate W. On the other hand, the chemical solution 144 according to an exemplary embodiment of the present inventive concept may be provided at the pressure of 1 atmosphere, which is an atmospheric pressure. The surfactant in the chemical solution 144 may adsorb and remove fine process particles from the substrate W. Thus, the cleaning efficiency 462 of the chemical solution 144 according to an exemplary embodiment of the present inventive concept may be higher than the cleaning efficiency 464 of the general SC-1 solution with respect to the fine process particles 146 disposed on the substrate W.

FIG. 4 illustrates an embodiment of the chemical solution supply unit 460 of FIG. 2 according to an exemplary embodiment of the present inventive concept. Referring to FIG. 4, the chemical solution supply unit 460 may circulate the chemical solution 144. Alternatively, the chemical solution supply unit 460 may mix the chemical solution 144 in the first and second chemical solution baths 562 and 564. The chemical solution supply unit 460 may include a source tank 510, a pump 520, a source filter 530, a second DI water supply unit 540, and a mixer 550.

The source tank 510 may store a chemical source 512. The chemical source 512 may include the surfactant and/or the organic solvent. The chemical source 512 may include the surfactant of about 10% and the organic solvent of about 90%. Alternatively, the chemical source 512 may include the surfactant of about 10%, the DI water of about 10% to about 80%, and the organic solvent of about 10% to about 80%. In one example, the surfactant in the organic solvent and DI water may have a concentration of 0.32 M.

The pump 520 may provide the chemical source 512 into the mixer 550. When a supply valve 522 is opened, the chemical source 512 may be provided into the mixer 550. In addition, the pump 520 may circulate the chemical source 512 through a circulation line 532. A circulation valve 534 may control the chemical source 512 in the circulation line 532. The supply valve 522 and the circulation valve 534 may alternately operate with respect to each other. For example, when the supply valve 522 is closed, the circulation valve 534 may be opened to circulate the chemical source 512. When the supply valve 522 is opened, the circulation valve 534 may be closed.

The source filter 530 may be connected to the circulation line 532. The source filter 530 may remove impurities in the chemical source 512. For example, the source filter 530 may remove impurities having sizes of 50 μm or greater.

The second DI water supply unit 540 may provide second DI water 514 into the mixer 550. While not shown, the second DI water supply unit 540 may be fluidly coupled to an external DI water supply source. In some embodiments, a supply amount of the second DI water 514 may be from about 10 times to about 100 times more than a supply amount of the chemical source 512. Thus, the chemical source 512 may be diluted with the second DI water 514. In this case, the surfactant of the chemical solution 144 may have a concentration of from about 0.03 M to about 0.003 M in the diluted solution. For example, the supply amount of the second DI water 514 may be about 30 times more than the supply amount of the chemical source 512. In this case, the surfactant of the chemical solution 144 may have a concentration of about 0.01 M in the diluted solution.

The mixer 550 may mix the chemical source 512 with the second DI water 514 to generate the chemical solution 144. The mixer 550 may also generate cleaning particles 518 in the chemical solution 144. The cleaning particles 518 may be different from general micelles (not shown). The general micelles may be generated when reaching a critical micelle concentration or higher. On the other hand, the cleaning particles 518 of the chemical solution 144 may be generated by reduction in solubility. In other words, the cleaning particles 518 of the chemical solution 144 may be generated at or above a saturation concentration of the chemical solution 144. However, a size distribution of the cleaning particles 518 may vary by mixing the chemical solution 144.

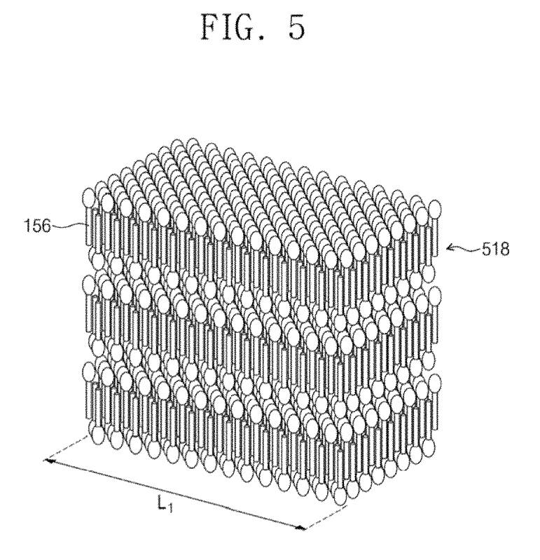

FIG. 5 illustrates an embodiment of the cleaning particles 518 of FIG. 4 according to an exemplary embodiment of the present inventive concept. The cleaning particles 518 may be formed by self-assembly of surfactant molecules 156. In some embodiments, the cleaning particle 518 may have a hexahedral shape and/or cubic shape, unlike the general micelle having a spherical shape. For example, the cleaning particle 518 may have a lateral length L₁ of from about 20 μm to about 200 μm. In other words, a length of one side of the hexahedral shape may range from about 20 μm to about 200 μm. The cleaning particle 518 of cubic shape may have a size and/or a diagonal length of from about 20\sqrt{3} μm to about 200\sqrt{3} μm.

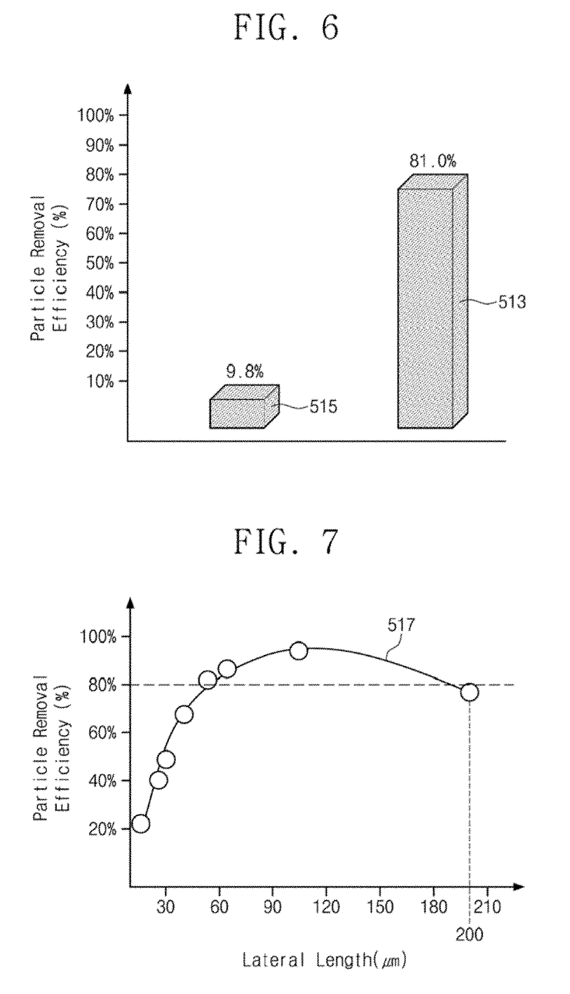

FIG. 6 illustrates a process particle removal efficiency 513 of the chemical solution 144 having the cleaning particles 518 of FIG. 5 and a process particle removal efficiency 515 of the chemical solution 144 not including the cleaning particles 518 according to an exemplary embodiment of the present inventive concept.

Referring to FIG. 6, the process particle removal efficiency 513 of the chemical solution 144 having the cleaning particles 518 may be higher than the process particle removal efficiency 515 of the chemical solution 144 not including the cleaning particles 518. This may be due to the cleaning particles 518 that can adsorb and remove the process particles 146. The impact of the cleaning particles 518 may be expressly illustrated in FIG. 6. FIG. 6 shows that the process particle removal efficiency 513 of the chemical solution 144 having the cleaning particles 518 may be about 81.0%. On the other hand, the process particle removal efficiency 515 of the chemical solution 144 not including the cleaning particles 518 may be about 9.8%. Referring back to FIG. 4, in one embodiment, the mixer 550 may include a gas compression mixer. When the mixer 550 is in the form of the gas compression mixer, the time for mixing particles in the mixer 550 may be minimized. In another embodiment, as shown in FIG. 4, the mixer 550 may include chemical solution baths 560, circulation filters 570, a circulation pipe 580, and/or a gas supply unit 590.

The chemical solution baths 560 may store the chemical solution 144. In some embodiments, the chemical solution baths 560 may include a first chemical solution bath 562 and a second chemical solution bath 564. The first chemical solution bath 562 may be connected to the supply valve 522. The first chemical solution bath 562 and the second chemical solution bath 564 may have the same size. Each of the first and second chemical solution baths 562 and 564 may store about 8 liters of the chemical solution 144. The first chemical solution bath 562 and the second chemical solution bath 564 may have a first exhaust valve 563 and a second exhaust valve 565, respectively. The first exhaust valve 563 may be connected to an upper portion of the first chemical solution bath 562. The second exhaust valve 565 may be connected to an upper portion of the second chemical solution bath 564. A first DI water valve 552 may be connected between the first chemical solution bath 562 and the second DI water supply unit 540. A second DI water valve 554 may be connected between the second chemical solution bath 564 and the second DI water supply unit 540. In one example, the first and second DI water valves 552 and 554 may adjust supply rates of the second DI water 514 to the first chemical solution bath 562 and the second chemical solution bath 564, respectively.

The circulation filters 570 may be disposed in the chemical solution baths 560. In some embodiments, the circulation filters 570 may include a first circulation filter 572 and a second circulation filter 574. For example, the first circulation filter 572 may be disposed in the first chemical solution bath 562, and the second circulation filter 574 may be disposed in the second chemical solution bath 564. The circulation filters 570 may filter the cleaning particles 518 whose sizes are equal to or greater than a certain predetermined size.

FIG. 7 illustrates a removal efficiency 517 of the process particles 146 according to the lateral length L₁ of the cleaning particles 518 with the hexahedral shape of FIG. 5 according to an exemplary embodiment of the present inventive concept.

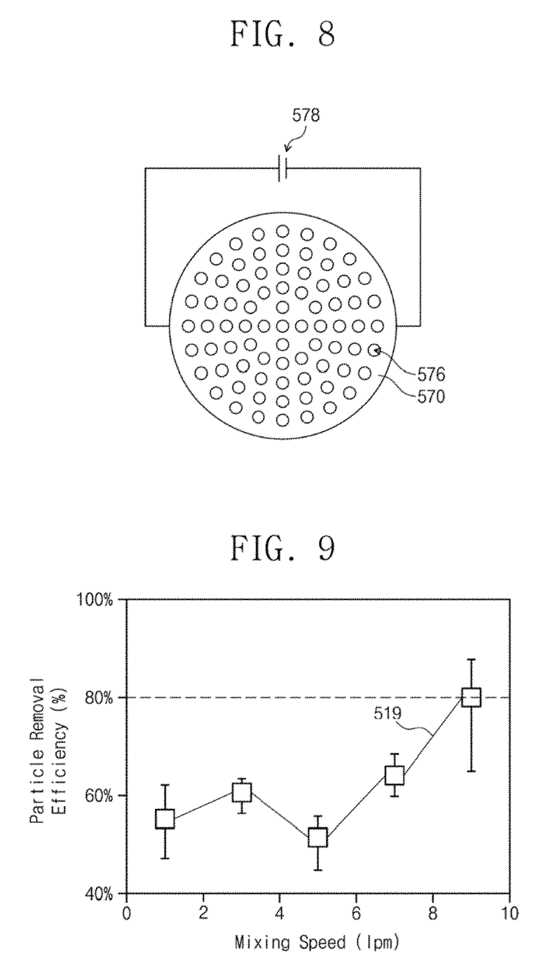

As shown in FIG. 7, the removal efficiency 517 of the process particles 146 may increase as the sizes (e.g., the lateral lengths L₁) of the cleaning particles 518 increase. For example, the cleaning particles 518 having the lateral lengths L₁ of about 20 μm or larger may have the removal efficiency 517 of the process particles 146, which is about 20% or greater. As shown in FIG. 7, when the lateral lengths L₁ of the cleaning particles 518 ranges from about 60 μm to about 200 μm, the removal efficiency 517 of the process particles 146 may be 80% or greater. When the lateral lengths L₃ of the cleaning particles 518 with the hexahedral shape are about 120 μm, the removal efficiency 517 of the process particles 146 may be in a range of from about 90% to about 95%. It may be noted that if the lateral lengths L₁ of the cleaning particles 518 are greater than about 200 μm, the cleaning particles 518 may damage the substrate W. If the lateral length L₁ is smaller than about 20 μm, the removal efficiency 517 of the process particles 146 may be lower than 20%. FIG. 8 illustrates an embodiment of the circulation filters 570 of FIG. 4 according to an exemplary embodiment of the present inventive concept.

Referring to FIGS. 5 and 8, each of the circulation filters 570 may have a plurality of pores 576. The plurality of pores 576 may be randomly disposed in the circulation filters 570. In one example, each of the plurality of pores 576 may have a diameter of from about 20\sqrt{3} μm to about 200\sqrt{3} μm. The plurality of pores 576 may filter the cleaning particles 518 whose sizes are greater than 200\sqrt{3} μm. In other words, the cleaning particles 518 of cubic shape having sizes of 200\sqrt{3} μm or less may pass through the plurality of pores 576 of the circulation filters 570. The cleaning particles 518 having sizes greater than 200\sqrt{3} μm may be filtered by the plurality of pores 576 of the circulation filters 570.

In another example, each of the plurality of pores 576 may have a diameter of from about 20 μm to about 200 μm. The plurality of pores 576 may filter the cleaning particles 518 whose sizes are greater than 200 μm. In other words, the cleaning particles 518 of hexahedral shape having sizes of 200 μm or less may pass through the plurality of pores 576 of the circulation filters 570. The cleaning particles 518 having sizes greater than 200 μm may be filtered by the plurality of pores 576 of the circulation filters 570.

Referring to FIGS. 4 and 8, the circulation filters 570 may be heated by applying a predetermined voltage and/or a current of a power supply 578. The circulation filters 570 may heat the cleaning particles 518 in the chemical solution 144. For example, the cleaning particles 518 may be dissolved in the chemical solution 144 at a temperature of about 50 degrees Celsius or greater. For example, the cleaning particles 518 having sizes greater than about 200\sqrt{3} μm may be dissolved in the chemical solution 144. Thus, the chemical solution 144 in the first and second chemical solution baths 562 and 564 may include the cleaning particles 518 having the sizes of about 2004 μm or less.

Referring to FIG. 4, the circulation pipe 580 may be connected between a lower portion of the first chemical solution bath 562 and a lower portion of the second chemical solution bath 564. The chemical solution 144 may be circulated between the first chemical solution bath 562 and the second chemical solution bath 564 through the circulation pipe 580. A diameter of the circulation pipe 580 may be smaller than a diameter of the first chemical solution bath 562 and/or a diameter of the second chemical solution bath 564. For example, the circulation pipe 580 may have the diameter of about 15.06 mm. The chemical solution 144 passing through the circulation pipe 580 may be mixed in the first and second chemical solution baths 562 and 564. In some embodiments, the circulation pipe 580 may be connected to the second nozzle 444. A chemical solution valve 446 may be connected between the circulation pipe 580 and the second nozzle 444 for controlling the flow of the chemical solution 144. For example, the chemical solution valve 446 may adjust an amount of the chemical solution 144 flowing through the second nozzle 444.

The gas supply unit 590 may alternately provide a nitrogen (N₂) gas into the first chemical solution bath 562 and the second chemical solution bath 564. The nitrogen (N₂) gas may be a compression gas. The gas supply unit 590 may have first and second gas supply valves 592 and 594. The first gas supply valve 592 may be connected between the gas supply unit 590 and the first chemical solution bath 562. When the first gas supply valve 592 is opened, the gas supply unit 590 may provide the nitrogen (N₂) gas into the first chemical solution bath 562. While the first gas supply valve 592 is opened, the second gas supply valve 594 and the first exhaust valve 563 may be closed. When the gas supply unit 590 provides the nitrogen (N₂) gas into the first chemical solution bath 562, the chemical solution 144 may move from the first chemical solution bath 562 into the second chemical solution bath 564. The second gas supply valve 594 may be connected between the gas supply unit 590 and the second chemical solution bath 564. When the second gas supply valve 594 is opened, the first gas supply valve 592 and the second exhaust valve 565 may be closed. When the second gas supply valve 594 is opened, the gas supply unit 590 may provide the nitrogen (N₂) gas into the second chemical solution bath 564. In this case, the chemical solution 144 may move from the second chemical solution bath 564 into the first chemical solution bath 562.

Referring to FIGS. 4 and 5, when the chemical solution 144 is circulated and/or mixed, the cleaning particles 518 may be generated in the chemical solution 144. If the chemical solution 144 is not circulated and/or mixed by the chemical solution supply unit 460, the cleaning particles 518 may be hardly generated in the chemical solution 144. Instead, the cleaning particles 518 may be generated by circulating and/or mixing the chemical solution 144. For example, a generation rate of the cleaning particles 518 may be proportional to a circulating speed and/or a mixing speed of the chemical solution 144.

FIG. 9 illustrates a process particle removal efficiency 519 with respect to a mixing speed of the chemical solution 144 of FIG. 4 according to an exemplary embodiment of the present inventive concept.

Referring to FIG. 9, the process particle removal efficiency 519 may increase as the mixing speed of the chemical solution 144 increases. The mixing speed of the chemical solution 144 may be defined as a flow amount of the chemical solution 144 passing through the circulation pipe 580 per minute. For example, when the chemical solution 144 is mixed at a mixing speed of about 8 lpm (liter per minute) to about 10 lpm, the process particle removal efficiency may range from about 60% to about 80%. In some embodiments, the cleaning particle 518 may have the lateral length L₁ of from about 80 μm to about 100 μm. When the mixing speed of the chemical solution 144 is 6 lpm or less, the process particle removal efficiency may be 60% or less. Moreover, if the chemical solution 144 is not mixed, the cleaning particles 518 may be hardly generated. In this case, even though the cleaning particles are generated, the lateral lengths L₁ of the cleaning particles 518 may be less than 20 μm.

A method for manufacturing a semiconductor device by using the aforementioned equipment 100 will be described hereinafter.

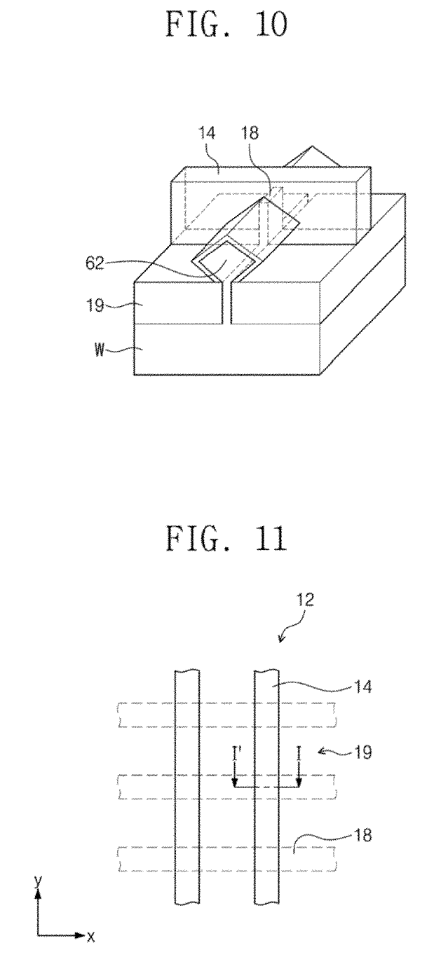

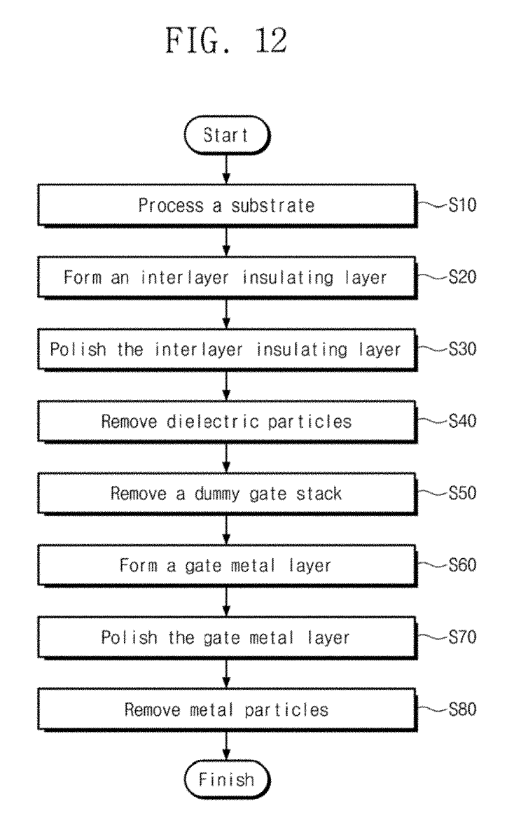

FIGS. 10 and 11 illustrate a semiconductor device 12 according to exemplary embodiments of the present inventive concepts. FIG. 12 illustrates a method for manufacturing the semiconductor device 12 of FIGS. 10 and 11 according to an exemplary embodiment of the present inventive concept.

Referring to FIGS. 10 and 11, the semiconductor device 12 may include a fin-field effect transistor (fin-FET). In some embodiments, the semiconductor device 12 may include a fin pattern 18, a device isolation layer 19, a word line 14, and stressors 62. The fin pattern 18 may protrude from a top surface of a substrate W. For example, as shown in FIG. 11, the fin pattern 18 may extend in an x-direction. The device isolation layer 19 may be formed on portions of both sidewalls of the fin pattern 18. The word line 14 may be formed on the fin pattern 18 and the device isolation layer 19. The word line 14 may extend in a direction intersecting the fin pattern 18. For example, as shown in FIG. 11, the word line 14 may extend in a y-direction.

Referring to FIG. 12, a method for manufacturing the semiconductor device 12 may include processing a substrate W (S10), forming an interlayer insulating layer (S20), polishing the interlayer insulating layer (S30), removing dielectric particles (S40), removing a dummy gate stack (S50), forming gate metal layers (S60), polishing the gate metal layers (S70), and removing metal particles (S80).

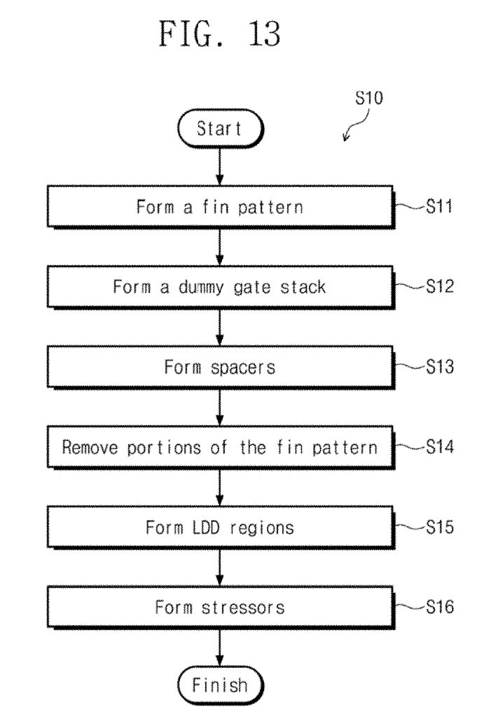

FIG. 13 illustrates an embodiment of the step S10 of processing the substrate W in FIG. 10 according to an exemplary embodiment of the present inventive concept.

Referring to FIG. 13, the step S10 of processing the substrate W may include a step of forming the fin pattern 18 and the stressors 62 on the substrate W. In some embodiments, the step S10 of processing the substrate W may include forming the fin pattern 18 (S11), forming a dummy gate stack (S12), forming spacers (S13), removing portions of the fin pattern 18 (S14), forming lightly doped drain (LDD) regions (S15), and forming the stressors (S16).

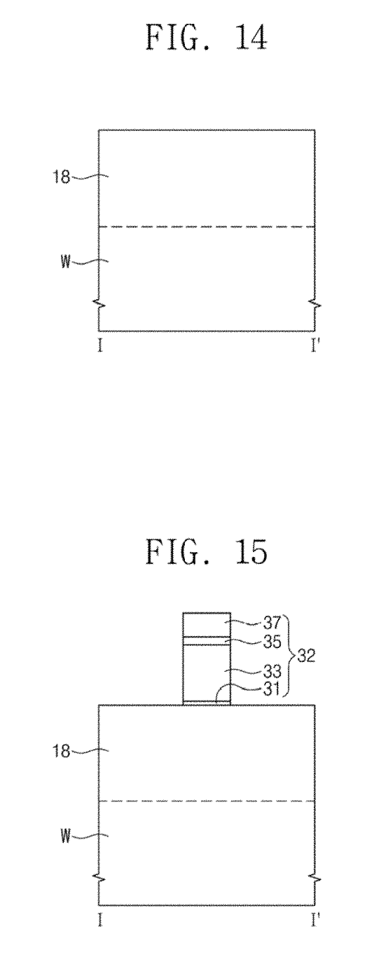

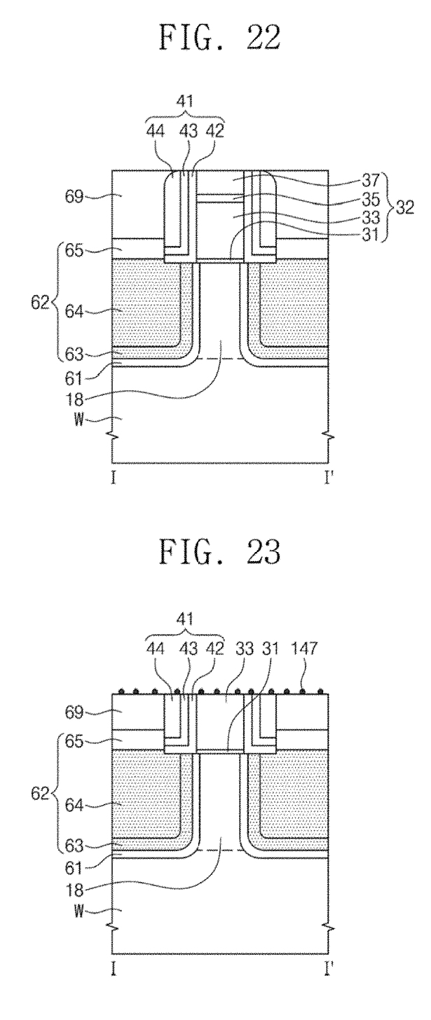

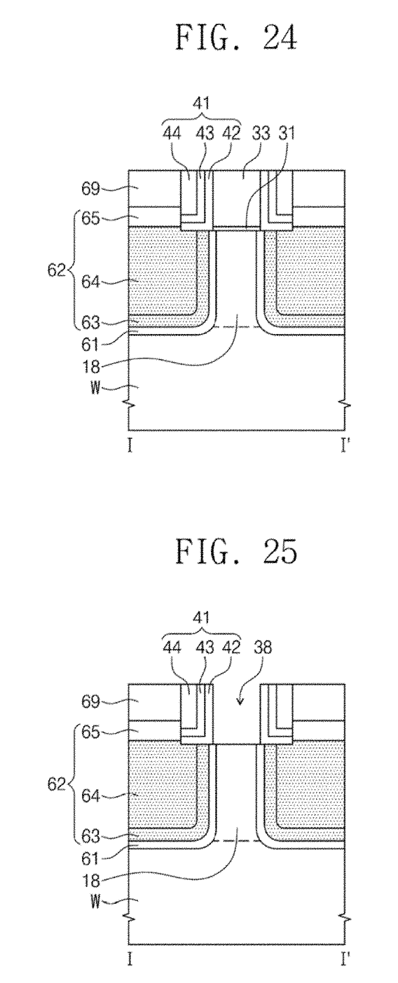

FIGS. 14 to 28 illustrate cross-sectional views taken along a line I-I′ of FIG. 11 to illustrate a method for manufacturing a semiconductor device according to exemplary embodiments of the inventive concept.

Referring to FIGS. 10 to 14, firstly, the fin pattern 18 may be formed on the substrate W (S11). The fin pattern 18 may include single-crystalline silicon grown from the substrate W. The fin pattern 18 may include conductive dopants. The device isolation layer 19 may be formed around the fin pattern 18. The device isolation layer 19 may be formed by a shallow-trench isolation (STI) method. For example, the device isolation layer 19 may include silicon oxide.

Referring to FIGS. 13 and 15, a dummy gate stack 32 may be formed on the fin pattern 18 and the device isolation layer 19 (S12). The dummy gate stack 32 may include a dummy gate dielectric pattern 31, a dummy gate electrode pattern 33, a buffer pattern 35, and a mask pattern 37. The dummy gate dielectric pattern 31, the dummy gate electrode pattern 33, the buffer pattern 35, and the mask pattern 37 may be formed by thin-layer deposition processes, a photolithography process, and an etching process.

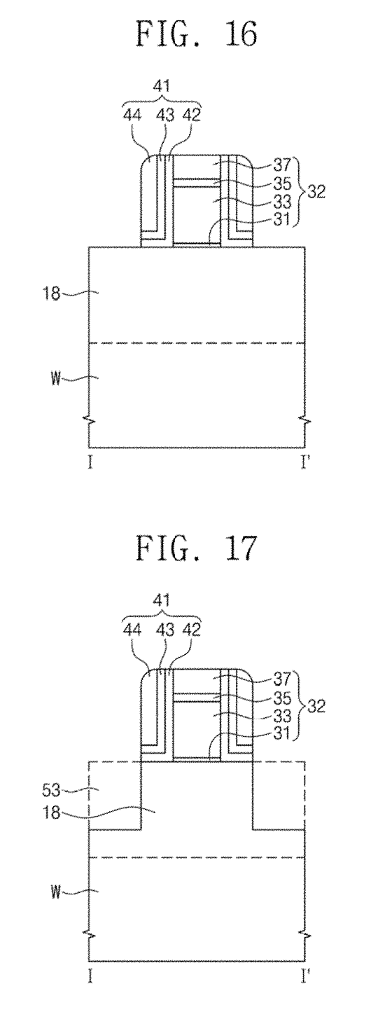

Referring to FIGS. 13 and 16, spacers 41 may be formed on both sidewalls of the dummy gate stack 32 (S13). The spacers 41 may include at least one of silicon oxide, silicon nitride, or silicon oxynitride. Each of the spacers 41 may include an inner spacer 42, an intermediate spacer 43, and an outer spacer 44. The inner spacer 42, the intermediate spacer 43, and the outer spacer 44 may be formed by a thin-layer deposition method and a self-aligned etching method.

Referring to FIGS. 13, 17, and 18, portions of the fin pattern 18 may be removed to form fin recesses 59 (S14). In some embodiments, the fin recesses 59 may be formed from preliminary fin recesses 53.

Referring to FIG. 17, the preliminary fin recesses 53 may be formed in the fin pattern 18 substantially along a periphery of the dummy gate stack 32 and the spacers 41. The preliminary fin recesses 53 may be formed by an anisotropic etching method. The preliminary fin recesses 53 may be self-aligned with the spacers 41.

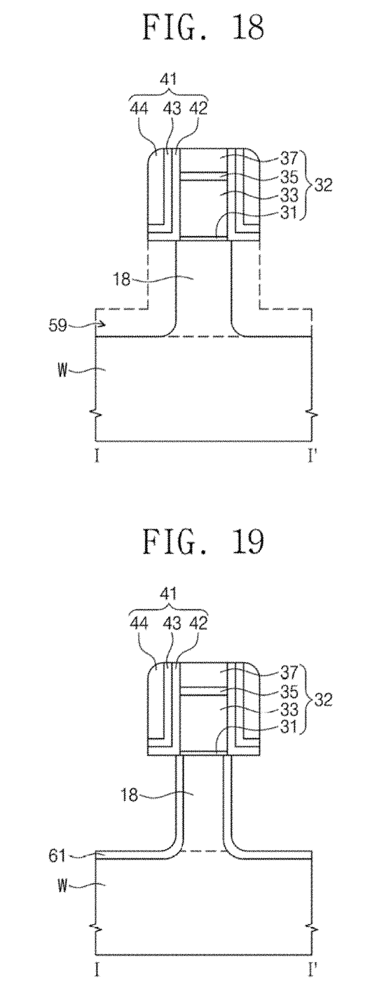

Referring to FIG. 18, the fin recesses 59 may be formed by isotropically etching the fin pattern 18 having the preliminary fin recesses 53. For example, the fin pattern 18 may be etched by a wet etching method. The fin recesses 59 may extend under the spacers 41.

Referring to FIGS. 13 and 19, LDD regions 61 may be formed at lower surfaces and sidewalls of the fin recesses 59 (S15). The LDD regions 61 may be formed by an ion implantation process. The LDD regions 61 may include dopants whose a conductivity type is different from a conductivity type of the dopants included in the fin pattern 18. The LDD regions 61 may have substantially uniform thicknesses along the substantially entire inner surfaces of the fin recesses 59. For example, the fin pattern 18 may include boron (B) dopants, and the LDD regions 61 may include arsenic (As) or phosphorus (P) dopants. Alternatively, the fin pattern 18 may include arsenic (As) or phosphorus (P) dopants, and the LDD regions 61 may include boron (B) dopants.

Referring to FIGS. 13, 20, and 21, stressors 62 may be formed in the fin recesses 59 (S16). In some embodiments, the stressors 62 may include embedded stressors or strain-inducing patterns. The stressors 62 may be source/drain electrodes. In some embodiments, each of the stressors 62 may include first, second, and third semiconductor layers 63, 64, and 65.

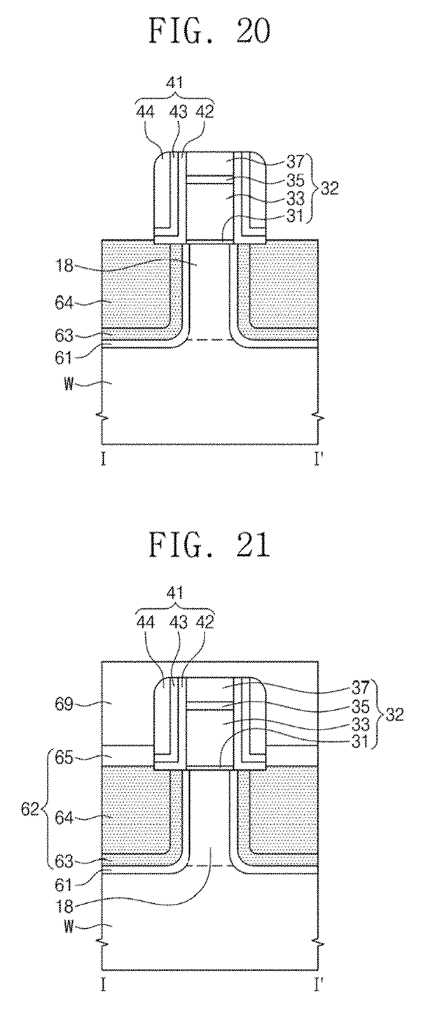

Referring to FIG. 20, the first and second semiconductor layers 63 and 64 may be formed in each of the fin recesses 59. Each of the first and second semiconductor layers 63 and 64 may be formed by a selective epitaxial growth (SEG) method, and may include silicon (Si), silicon carbide (SiC), silicon-germanium (SiGe), or any combination thereof. The second semiconductor layer 64 may completely fill each of the fin recesses 59. An upper portion of the second semiconductor layer 64 may be positioned to be higher than an upper portion of the fin pattern 18.

For example, the first semiconductor layer 63 may include boron (B)-doped SiGe formed by the SEG method. A germanium (Ge) content of the first and second semiconductor layers 63 and 64 may increase as a distance from the substrate W increases. The Ge content of the first semiconductor layer 63 may range from 10% to 25%. A boron (B) content in the first semiconductor layer 63 may be higher than a boron (B) content in the LDD region 61. The first semiconductor layer 63 may conformally cover the inner surface of each of the fin recesses 59. For example, as shown in FIG. 20, the first semiconductor layer 63 may be formed on the upper surface of the LDD region 61 which conformally covers the inner surface of each of the fin recesses 59. The second semiconductor layer 64 may include boron (B)-doped SiGe formed by the SEG method. The Ge content in the second semiconductor layer 64 may be higher than the Ge content in the first semiconductor layer 63. For example, the Ge content of the second semiconductor layer 64 may range from about 25% to about 50%. A boron (B) content in the second semiconductor layer 64 may be higher than the boron (B) content in the first semiconductor layer 63. Alternatively, each of the first and second semiconductor layers 63 and 64 may include silicon carbide (SiC). In other embodiments, the first and second semiconductor layers 63 and 64 may include silicon (Si) formed by the SEG method.

Referring to FIG. 21, the third semiconductor layer 65 may be formed on the second semiconductor layer 64. The third semiconductor layer 65 may include silicon (Si) formed by a SEG method.

Referring to FIGS. 12, 21, and 22, an interlayer insulating layer 69 may be formed on the stressors 62, the dummy gate stack 32, and the spacers 41 (S20). The interlayer insulating layer 69 may include a dielectric material formed by a thin-layer deposition method. For example, the interlayer insulating layer 69 may include silicon oxide, silicon nitride, silicon oxynitride, or any combination thereof.

Referring to FIGS. 1, 12, and 23, the polishing apparatus 130 may polish the interlayer insulating layer 69 to expose the dummy gate electrode pattern 33 (S30). The polishing apparatus 130 may polish the interlayer insulating layer 69 by a chemical mechanical polishing (CMP) method. When the interlayer insulating layer 69 is polished or planarized, the mask pattern 37 and the buffer pattern 35 may be removed. The interlayer insulating layer 69, the spacers 41, and the dummy gate electrode pattern 33 may have exposed upper surfaces, which are substantially coplanar with each other. A composition of slurry used in the CMP method may include oxide polishing particles of about 0.01 wt % to about 10 wt %, an oxidizer of about 0.1 wt % to about 10 wt %, a polishing adjuster of about 0.5 wt % to about 10 wt %, a surfactant of about 0 wt % to about 3 wt %, a pH adjuster of about 0 wt % to about 3 wt %, and third DI water of about 64 wt % to about 99.39 wt %. After the CMP process, dielectric particles 147 may remain on at least one of the top surfaces of the interlayer insulating layer 69, the spacers 41, or the dummy gate electrode pattern 33.

Referring to FIGS. 2, 12, and 24, the cleaning apparatus 140 may remove the dielectric particles 147 to clean the substrate W (S40). The dielectric particles 147 may be removed by the first DI water 142 and/or the chemical solution 144.

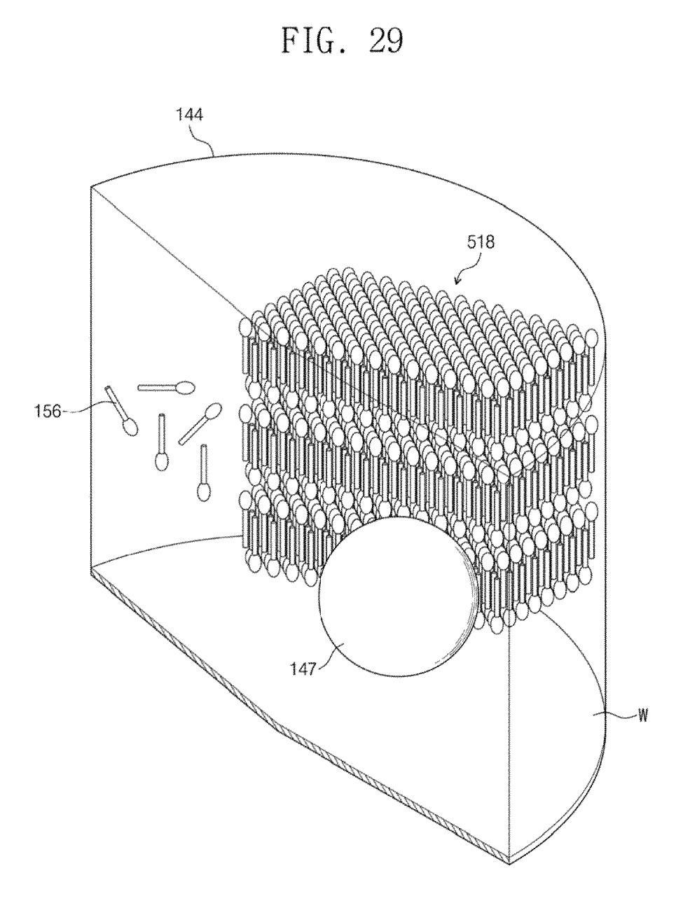

FIG. 29 illustrates the dielectric particles 147 of FIG. 23 and the cleaning particles 518 according to an exemplary embodiment of the present inventive concept.

Referring to FIG. 29, the cleaning particles 518 may adsorb the dielectric particles 147. The cleaning particles 518 may physically and/or chemically adsorb the dielectric particles 147. The chemical solution 144 may separate the cleaning particles 518 and the dielectric particles 147 from the substrate W. For example, the chemical solution 144 may remove the dielectric particles 147 from the substrate W at the removal efficiency of about 80% or greater.

Referring to FIGS. 12 and 25, the dummy gate electrode pattern 33 and the dummy gate dielectric pattern 31 may be removed to form a trench 38 (S50). The fin pattern 18 may be exposed in the trench 38. For example, the dummy gate dielectric pattern 31 and the dummy gate electrode pattern 33 may be removed by a wet etching method. An etchant used in the wet etching method may include a strong acid solution such as hydrofluoric acid, hydrochloric acid, sulfuric acid, or nitric acid.

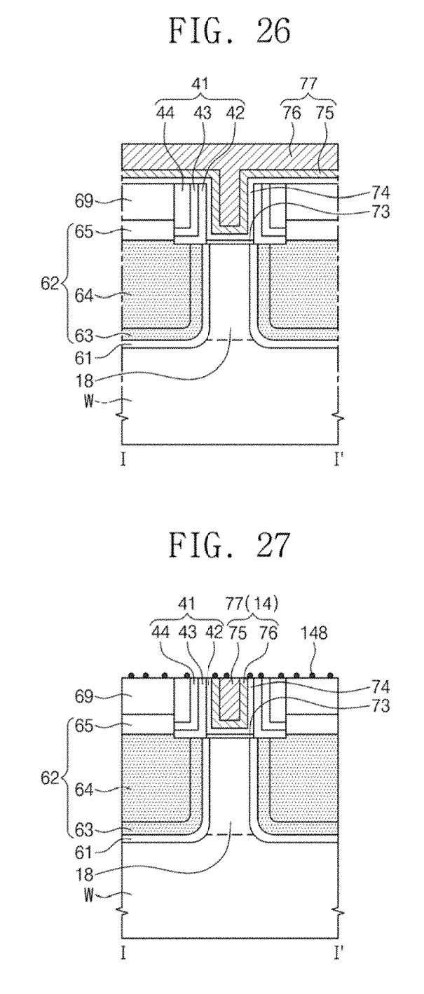

Referring to FIGS. 12 and 26, first and second gate dielectric layers 73 and 74 and a gate metal layer 77 may be formed in the trench 38 and on the interlayer insulating layer 69 (S60). The first and second gate dielectric layers 73 and 74 and the gate metal layer 77 may be formed by a thermal oxidation method, a chemical vapor deposition (CVD) method, and/or an atomic layer deposition (ALD) method.

The first gate dielectric layer 73 may be formed on the fin pattern 18. The first gate dielectric layer 73 may be defined as an interfacial oxide layer. The first gate dielectric layer 73 may be formed by thermally oxidizing the fin pattern 18. For example, the first gate dielectric layer 73 may include silicon oxide. The first gate dielectric layer 73 may be formed on a lower surface of the trench 38. Alternatively, the dummy gate dielectric pattern 31 may be used as the first gate dielectric layer 73. In other words, the dummy gate dielectric pattern 31 may remain when the trench 38 is formed, and the remaining dummy gate dielectric pattern 31 may be used as the first gate dielectric layer 73. For example, the first gate dielectric layer 73 may have a thickness of about 1 nm.

The second gate dielectric layer 74 may be formed on the first gate dielectric layer 73, the spacers 41, and the interlayer insulating layer 69. The second gate dielectric layer 74 may be formed by the ALD method. The second gate dielectric layer 74 may include a high-k dielectric material. For example, the second gate dielectric layer 74 may include hafnium dioxide (HfO₂), hafnium silicon oxide (HfSiO), titanium dioxide (TiO₂), tantalum oxide (Ta₂O₅, or TaO₂). The gate metal layer 77 may have a thickness of from about 1 nm to about 49 nm.

The gate metal layer 77 may cover the second gate dielectric layer 74. The gate metal layer 77 may completely fill the trench 38 and may cover the substrate W. In some embodiments, as shown in FIG. 26, the gate metal layer 77 may include a work-function layer 75 and a low-resistance layer 76.

The work-function layer 75 may be formed on the second gate dielectric layer 74. In some embodiments, the work-function layer 75 may be formed by an ALD method. For example, the work-function layer 75 may include an N-work-function metal or a P-work-function metal. For example, the N-work-function metal may include titanium carbide (TiC), titanium aluminide (TiAl), tantalum aluminide (TaAl), hafnium aluminide (HfAl), or any combination thereof, and the P-work-function metal may include titanium nitride (TiN).

The low-resistance layer 76 may be formed on the work-function layer 75. In some embodiments, the low-resistance layer 76 may be formed by a sputtering method. For example, the low-resistance layer 76 may include tungsten (W), tungsten nitride (WN), titanium (Ti), titanium nitride (TiN), titanium aluminide (TiAl), titanium aluminum carbide (TiAlC), tantalum (Ta), tantalum nitride (TaN), conductive carbon, or any combination thereof.

Referring to FIGS. 1, 12, and 27, the polishing apparatus 130 may polish the gate metal layer 77 to form the word line 14 (S70). The word line 14 may be the polished or planarized gate metal layer 77. The gate metal layer 77 may be planarized by a CMP method. The interlayer insulating layer 69, the spacers 41, the second gate dielectric layer 74, and the planarized gate metal layer 77 may have upper surfaces, which are substantially coplanar with each other and are exposed. Metal particles 148 may remain on at least one of the upper portion of the interlayer insulating layer 69, the spacers 41, the second gate dielectric layer 74, or the planarized gate metal layer 77.

Referring to FIGS. 2, 12, and 28, the cleaning apparatus 140 may remove the metal particles 148 to clean the substrate W (S80). For example, the metal particles 148 on the planarized gate metal layer 77 (word line 14), the spacers 41, and the interlayer insulating layer 69 may be removed by providing the first DI water 142 and the chemical solution 144 to the planarized gate metal layer 77 (word line 14), the spacers 41, and the interlayer insulating layer 69.

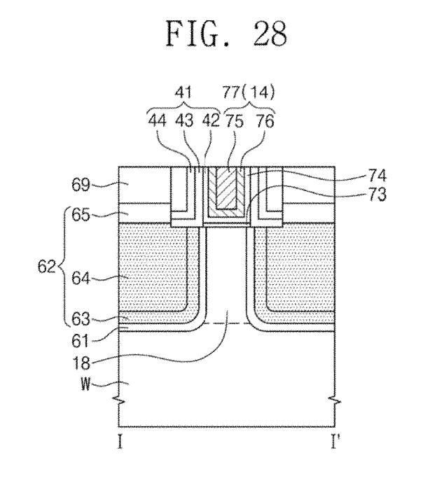

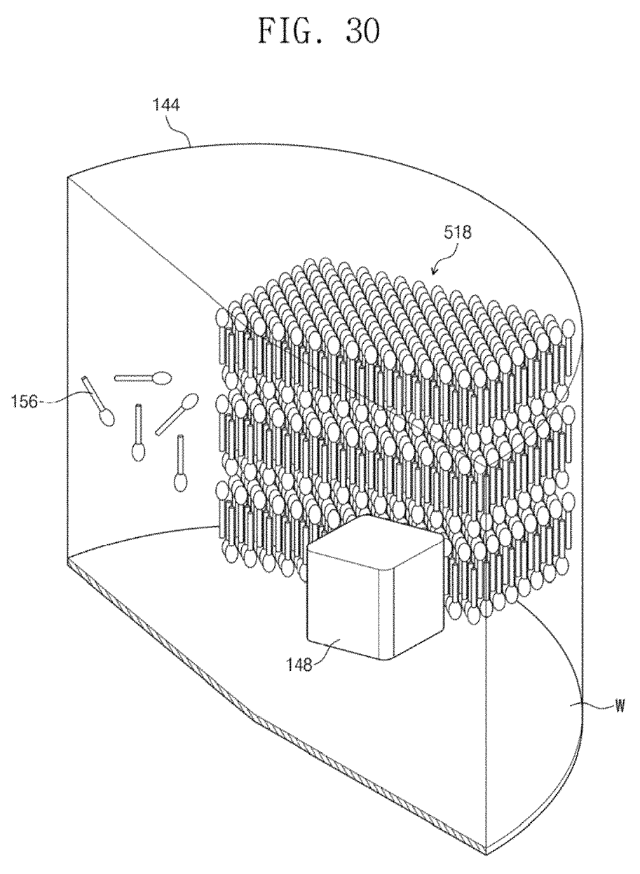

FIG. 30 illustrates the metal particles 148 of FIG. 28 and the cleaning particles 518 according to an exemplary embodiment of the present inventive concept.

Referring to FIG. 30, the cleaning particles 518 may adsorb the metal particles 148. The cleaning particles 518 may physically and/or chemically adsorb the metal particles 148. The chemical solution 144 may separate the cleaning particles 518 and the metal particles 148 from the substrate W. For example, the chemical solution 144 may remove the metal particles 148 from the substrate W at the removal efficiency of about 80% or greater.

According to some embodiments of the inventive concepts, the cleaning composition may include ammonium hexadecyl sulfate having the cleaning particles. The cleaning particles may adsorb fine process particles to remove the fine process particles. The cleaning composition may minimize damage to the upper portion of the substrate. A cleaning efficiency of the cleaning composition may be better than that of a SC-1 solution with respect to the fine process particles.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

1. A cleaning composition comprising:
a surfactant; deionized (DI) water, and an organic solvent,
wherein the surfactant has a concentration of from about 0.03 M to about 0.003 M.

2. The cleaning composition of claim 1, wherein the surfactant is a sulfate-based surfactant.

3. The cleaning composition of claim 1, wherein the surfactant has a structure represented by a following chemical formula 1,
(R¹—O)ₐ—(R²—O)_{b}—SO₃NH₄, [Chemical formula 1]
where each of “a” and “b” is an integral number of 0 to 18, “a” and “b” are not zero (0) at the same time, “R¹” and “R²” are a substituted or unsubstituted alkyl or alkylene group having a carbon number of 1 to 18 or a substituted or unsubstituted arylene group having a carbon number of 6 to 14, and (R¹—O) or (R²—O) is randomly repeated or is repeated in a block form when “a” or “b” is 3 or greater.

4. The cleaning composition of claim 3, wherein “a” is 1, the carbon number of “R¹” is 16, “b” is 0, and the surfactant is ammonium hexadecyl sulfate.

5. The cleaning composition of claim 1, wherein the surfactant generates cleaning particles when the surfactant is mixed in the DI water.

6. The cleaning composition of claim 5, wherein the cleaning particle has one of a hexahedral shape or a cubic shape.

7. The cleaning composition of claim 6, wherein a length of one side of the cleaning particle with a hexahedral shape ranges from about 20 micrometers to about 200 micrometers.

8. The cleaning composition of claim 6, wherein a length of one side of the cleaning particle with the hexahedral shape is about 120 micrometers.

9. The cleaning composition of claim 1, wherein the cleaning composition has a pH of 9 or greater.

10. The cleaning composition of claim 1, wherein the organic solvent includes isopropyl alcohol (IPA), ethyl alcohol (EtOH), methanol (MeOH), dimethyl sulfoxide (DMSO), dimethylformamide (DMF), terahydrofuran (THF), ethylene glycol (EG), propylene glycol (PG), N-methyl-2-pyrrolidone (NMP), or N-ethylpryrrolidone (NEP).

11. A cleaning apparatus comprising:
a chuck receiving a substrate;
a nozzle providing a chemical solution onto the substrate; and
a chemical solution supply unit supplying the chemical solution to the nozzle, the chemical solution supply unit mixing the chemical solution to generate cleaning particles,
wherein the chemical solution comprises:
a surfactant; deionized (DI) water; and an organic solvent,
wherein the surfactant has a concentration of from about 0.03 M to about 0.003 M.

12. The cleaning apparatus of claim 11, wherein the chemical solution supply unit comprises:
a source tank storing a cleaning source of the chemical solution;
a DI water supply unit providing DI water with which the cleaning source is diluted; and
a mixer mixing the DI water and the cleaning source with each other to generate the chemical solution and to generate the cleaning particles in the chemical solution.

13. The cleaning apparatus of claim 12, wherein the mixer comprises:
a plurality of chemical solution baths storing the chemical solution;
a circulation pipe connecting the chemical solution baths to each other, and
a gas supply unit alternately providing a compression gas into one of the plurality of chemical solution baths to circulate the chemical solution between the plurality of chemical solution baths.

14. The cleaning apparatus of claim 13, wherein the mixer further comprises: filters disposed in the plurality of chemical solution baths and having a plurality of pores filtering the cleaning particles,
wherein each of the plurality of pores has a diameter of from about 20\sqrt{3} to about 200\sqrt{3} micrometers.

15. The cleaning apparatus of claim 14, wherein the filters are connected to a power supply to heat the cleaning particles having diameters greater than the diameters of the plurality of pores by the filters to dissolve the cleaning particles having diameters greater than the diameters of the plurality of pores in the chemical solution.

16. A method for manufacturing a semiconductor device, the method comprising:
processing a substrate;
forming an interlayer insulating layer on the substrate;
polishing the interlayer insulating layer; and
providing a cleaning composition onto the interlayer insulating layer to remove first process particles,
wherein the cleaning composition comprises:
a surfactant; deionized (DI) water; and an organic solvent,
wherein the surfactant has a concentration of from about 0.03 M to about 0.003 M.

17. The method of claim 16, wherein the surfactant is mixed with the DI water to generate cleaning particles, and
wherein the cleaning particles adsorb the first process particles.

18. The method of claim 16, wherein the processing of the substrate comprises:
forming a fin pattern protruding from the substrate;
forming a dummy gate stack on the fin pattern;
forming spacers on both sidewalls, opposite to each other, of the dummy gate stack;
removing portions of the fin pattern to form recesses;
forming lightly doped drain (LDD) regions at lower surfaces and sidewalls of the recesses; and
forming stressors on the LDD regions.

19. The method of claim 18, further comprising:
removing the dummy gate stack to form a trench;
forming a gate metal layer in the trench;
polishing the gate metal layer to form a word line; and
providing the cleaning composition onto the word line, the spacers, and the interlayer insulating layer to remove second process particles.

20. The method of claim 19, wherein the surfactant is mixed with the DI water to generate cleaning particles, and
wherein the cleaning particles adsorb the second process particles.

21-22. (canceled)
